(19) United States
(12) Patent Application Publication
(10) Pub. No.: US 2024/0388262 A1
(43) Pub. Date: Nov. 21, 2024

(54) AMPLIFIER CIRCUITS

(71) Applicant: Infineon Technologies AG, Neubiberg (DE)

(72) Inventor: Dieter Draxelmayr, Villach (AT)

(21) Appl. No.: 18/659,143

(22) Filed: May 9, 2024

(30) Foreign Application Priority Data
May 17, 2023 (DE) 10 2023 113 040.4

(51) Int. Cl. H03F 3/16

(52) U.S. Cl. CPC H03F 3/16; H03F 2200/366

(57) ABSTRACT

An amplifier circuit includes first and second transistors, the first controlled terminals of which are connected to one another and to a first reference potential, and the second controlled terminals of which are connected to a second reference potential. The first and second transistors are of a first conductivity type. The amplifier circuit also includes a first circuit connected on the input side to the second controlled terminal of the first transistor and controlled by a first voltage, and a second circuit connected on the input side to the second controlled terminal of the second transistor and controlled by a second voltage. The first circuit and/or the second circuit has a transistor of a second conductivity type, to the control terminal of which the first voltage or the second voltage is applied.

### REFERENCE TO RELATED APPLICATIONS

This application claims priority to German Patent Application 10 2023 113 040.4, filed on May 17, 2023, the contents of which are hereby incorporated by reference in their entirety.

### TECHNICAL FIELD

The disclosure relates to amplifier circuits.

### BACKGROUND

Occasionally, high voltages need to be handled by devices that do not have appropriate dielectric strength. An example of this is surge-tolerant input/output (I/O-IOs) interfaces.

A common technical scenario is the buffer storage of an analog input voltage. In this case, it turns out that conventional operational amplifier input structures do not work.

FIG. 9 shows an operational transconductance amplifier (OTA) 900. This is a very reliable and very robust architecture. The OTA 900 comprises a first transistor M1 and a second transistor M2. Both transistors are of the same first conductivity type (n conductivity type). A first input voltage Vinp is applied to a control terminal 902 of the first transistor M1 and a second input voltage Vinn is applied to a control terminal 908 of the second transistor M2. A first controlled terminal 904 of the first transistor M1 is connected directly to a first controlled terminal 910 of the second transistor M2 and, by means of a current source transistor M0 (at the control input 914 of which a bias voltage BIAS is applied) to a first reference potential GND. The OTA 900 further comprises a current mirror 916 having a first current mirror transistor P1 and a second current mirror transistor P2 which is directly connected on the input side to a second controlled terminal 906 of the first transistor M1 and is connected directly on the output side to a second controlled terminal 912 of the second transistor M2. A connection node 918 between the output of the current mirror 916 and the second controlled terminal 912 of the second transistor M2 forms an output at which an output current Iout of the OTA 900 is provided. The first current mirror transistor P1 and the second current mirror transistor P2 are of a second conductivity type (p conductivity type) which is opposite to the first conductivity type.

FIG. 10 shows another amplifier circuit 1000. The amplifier circuit 1000 comprises what is known as folded-cascode architecture. It may also be extended with a complementary stage to form a rail-to-rail amplifier. The amplifier circuit 1000 comprises a pair of input differential transistors M1, M2 and a pair of folded-cascode transistors P3, P4, the conductivity type of which is different from the conductivity type of the input differential transistors M1, M2. Furthermore, a current source 1002 having a first current source transistor P1 and a second current source transistor P2 is provided. First controlled terminals 1004, 1010 of the input differential transistors M1, M2 are connected directly to one another and, by means of a third current source transistor M0 (at the control input 1014 of which a first bias voltage BIAS is applied), to a first reference potential GND.

A first controlled terminal of the first current source transistor P1 is connected to a first connection node 1016, to which a second controlled terminal 1006 of the first transistor M1 is also connected. A first controlled terminal 1022 of a first cascode transistor P3 of the pair of folded-cascode transistors P3, P4 is also connected to the first connection node 1016. A second bias voltage BIAS2 is applied to a control terminal 1018 of the first cascode transistor P3 and a first output current Iout1 is provided at a second controlled terminal 1020 of the first cascode transistor P3.

A first controlled terminal of the second current source transistor P2 is connected to a second connection node 1024, to which a second controlled terminal 1012 of the second transistor M2 is also connected. A first controlled terminal 1030 of a second cascode transistor P3 of the pair of folded-cascode transistors P3, P4 is also connected to the second connection node 1024. The second bias voltage BIAS2 is applied to a control terminal 1026 of the second cascode transistor P4 and a second output current Iout2 is provided at a second controlled terminal 1028 of the second cascode transistor P4.

FIG. 11 shows yet another amplifier circuit 1100. The amplifier circuit 1100 from FIG. 11 is very similar to the amplifier circuit 1000 from FIG. 10, which is why only the differences are explained in more detail below.

The amplifier circuit 1100 from FIG. 11 additionally comprises a third transistor M3 and a fourth transistor M4 which are of the same conductivity type as the input differential transistors M1, M2. The third transistor M3 is connected in series with the first transistor M1, between the second controlled terminal 1006 of the first transistor M1 and the first current source transistor P1. The fourth transistor M4 is connected in series with the second transistor M2, between the second controlled terminal 1012 of the second transistor M2 and the second current source transistor P2. The third transistor M3 and the fourth transistor M4 are used as protective transistors for the input differential transistors M1, M2.

Furthermore, an electrical resistor Rn is provided, the first terminal of which is connected to the first controlled terminals 1004, 1010 of the input differential transistors M1, M2 and to a first controlled terminal of the third current source transistor M0, the second controlled terminal of which is connected to the first reference potential GND. A second terminal of the electrical resistor Rn is connected to a third connection node 1102, to which a control terminal 1104 of the third transistor M3 and a control terminal 1106 of the fourth transistor M4 is also connected. Furthermore, a fourth current source transistor P5 is provided, which is of the same conductivity type as the first current source transistor P1 and the second current source transistor P2, and the first controlled terminal 1108 of which is also connected to the third connection node 1102. A voltage which is derived from a weighted average of the first input voltage Vinp and the second input voltage Vinn is generated at the third connection node.

The protective transistors M3 and M4 are actuated indirectly by the input voltages Vinn and Vinp. The resistor Rn is used to shift the level of the input voltage which is averaged from the input voltages Vinn and Vinp.

However, such a configuration does not allow very high input voltages, since the input differential transistors M1, M2 would go into saturation and the amplifier circuit 1100 would lose gain as a result.

### BRIEF DESCRIPTION OF THE DRAWINGS

Exemplary embodiments of the disclosure are illustrated in the figures and are explained in more detail below.

In the figures:

FIG. 1 shows a circuit according to various aspects of the present disclosure;

FIG. 2 shows an amplifier circuit according to various aspects of the present disclosure;

FIG. 3 shows an amplifier circuit according to various aspects of the present disclosure;

FIG. 4 shows an amplifier circuit according to various aspects of the present disclosure;

FIG. 5 shows an amplifier circuit according to various aspects of the present disclosure;

FIG. 6 shows an amplifier circuit according to various aspects of the present disclosure;

FIG. 7 shows an amplifier circuit according to various aspects of the present disclosure;

FIG. 8 shows a circuit for generating a single-sided rail-to-rail output voltage or a rail-to-rail output current;

FIG. 9 shows a transconductance amplifier;

FIG. 10 shows an amplifier circuit in a folded-cascode architecture;

FIG. 11 shows another amplifier circuit in a folded-cascode architecture; and

FIG. 12 shows an amplifier circuit according to various aspects of the present disclosure.

### DETAILED DESCRIPTION

In the following detailed description, reference is made to the accompanying drawings, which form part of said description and in which specific embodiments in which the disclosure may be carried out are shown for illustrative purposes. In this respect, directional terminology such as for instance “top”, “bottom”, “at the front”, “at the rear”, “front”, “rear”, etc. is used with reference to the orientation of the described figure(s). Since components of embodiments may be positioned in a number of different orientations, the directional terminology is used for illustrative purposes and is in no way limiting. It goes without saying that other embodiments may be used and structural or logical changes may be made without departing from the scope of protection of the present disclosure. It goes without saying that the features of the various exemplary embodiments described herein may be combined with one another, unless specifically indicated otherwise. The following detailed description should therefore not be interpreted in a restrictive sense, and the scope of protection of the present disclosure is defined by the appended claims.

Within the scope of this description, the terms “linked,” “connected,” and “coupled” are used to describe both a direct and an indirect link, a direct or indirect connection, and direct or indirect coupling. Identical or similar elements are provided with identical reference signs in the figures where expedient.

Examples described here may include high voltages and low voltages. Some examples described here may involve circuits for processing voltages in a range of approximately 5 V, while transistors with a recommended operating voltage in a range of 2.5 V are used. In conjunction with these examples, 5 V can be understood as high voltage, while 2.5 V can be understood as low voltage. In combination with other examples described herein, any voltage greater than a recommended operating voltage of a transistor or an applicable operating voltage applicable to transistors may be understood as high voltage, with a voltage equal to or less than the recommended operating voltage being understood as low voltage.

The recommended operating voltage may be a device-dependent (for example transistor-dependent) voltage or a device-dependent (for example transistor-dependent) potential between each control terminal, such as an apparatus or a base of a transistor, and a controlled terminal of the transistor, such as a source or a drain, a collector or an emitter. For example, the recommended operating voltage may be specified in a data sheet of the transistor. The recommended operating voltage (also referred to as the rated voltage) may be a voltage which is applied to the terminals of the transistor and allows for regular operation without damaging the transistor element through applying a surge voltage. Accordingly, a recommended operating voltage of a transistor (for example a gate-source voltage) may be VGSOP 2.5 volts and would be equivalent to a low voltage, and a maximum applicable operating voltage (which is usually greater than the associated recommended operating voltage) should be 3.25 V, for example, which corresponds to a permitted range (tolerance range) of 30% of the recommended voltage range.

Transistors used in various aspects of this disclosure may be planar transistors, fin transistors, or vertical transistors. The transistors may be field-effect transistors (FETs) or bipolar transistors. The transistors may be (for example normally off) metal-oxide semiconductor (MOS) FETs, for example n-channel MOSFETs (also referred to as n conductivity type MOSFETs) or p-channel MOSFETs (also referred to as p conductivity type MOSFETs). The transistors may be normally off field-effect transistors or normally on field-effect transistors. The transistors may comprise one or more control terminals (for example gate or base) and multiple controlled terminals (for example source or emitter and drain or collector).

Various aspects address a scenario in which a 5 V device (5 V supply, 5 V-IOs) is transferred to a manufacturing process which does not provide 5 V transistors.

Various aspects provide amplifier circuits (for example in the form of transconductance amplifiers) in which a high-voltage device (high supply voltage, high voltage at the IOs) can be realized using transistors whose applicable operating voltage is lower than the voltage of the high-voltage device without damaging the transistors.

Another example discloses a complete rail-to-rail buffer.

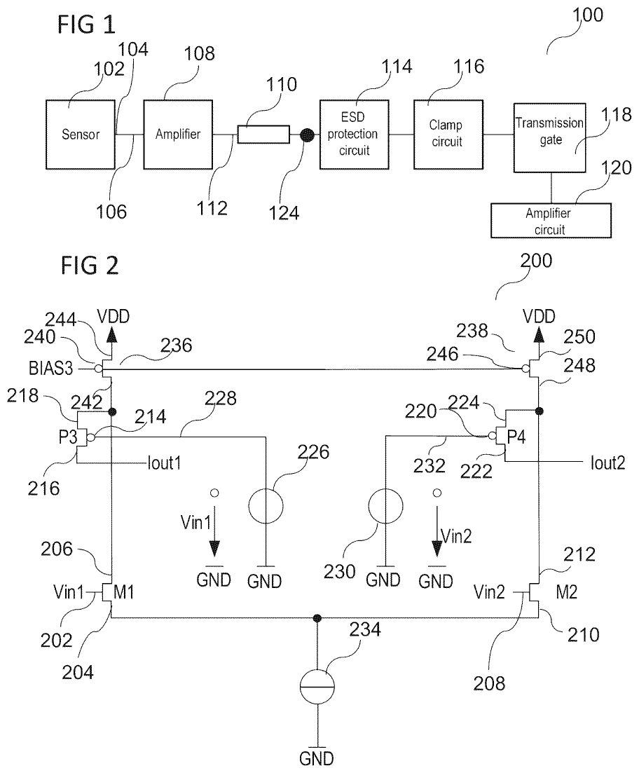

FIG. 1 shows a circuit 100 according to various aspects of the present disclosure. The circuit 100 shows a possible area of application for an amplifier circuit according to various aspects of the present disclosure. However, the amplifier circuits described below may also be used in other applications, generally in any desired and appropriate application for an amplifier circuit, for example a transconductance amplifier circuit.

The circuit 100 comprises an input 124. An external circuit delivers a signal to the input 124. The external circuit comprises, for example, a DC voltage interface, for example a sensor 102 having a sensor interface 104. The sensor 102 may be connectable to a power sink, for example one or more processors, for example one or more microcontrollers. The sensor 102 may be set up as a Hall sensor, a knocking sensor and/or a low-frequency sensor which uses frequencies below 1 MHz, or any other electronic sensor. Sensor signals 106 are provided at the sensor interface 104 and supplied to an amplifier 108 (for example implemented by means of an amplifier circuit according to various aspects of this disclosure, described in more detail below). The amplifier 108 amplifies the analog sensor signals 106 and provides amplified sensor signals 112 at its output.

An optional series resistor 110 may be provided between the amplifier 108 and the input 124 to limit a current which is able to flow into the circuit 100.

The current from the external circuit flows via the input 124 into the circuit 100.

Furthermore, there may optionally be provision for an electrostatic discharge (ESD) protection circuit 114 which may be connected to the input 124 of the circuit 100.

In addition, a clamp circuit 116 may be connected between the ESD protection circuit 114 and an optional transmission gate 118. The transmission gate 118 is connected on the output side to an additional amplifier circuit 120 (the additional amplifier circuit 120 may alternatively also be connected between the clamp circuit 116 and the transmission gate 118). The clamp circuit 116 protects the circuit 120 to be protected by ensuring that the clamp circuit 116 provides only a limited electrical voltage (illustratively the clamp voltage) to the circuit 120 to be protected. The ESD protection circuit 114 and/or the clamp circuit 116 and/or the transmission gate 118 and/or the additional amplifier circuit 120 may be integrated on a common chip or may be provided on individual chips.

There may of course also be provision for multiple sensors 102, which are then connected to an input of the circuit 120 to be protected, for example by means of a multiplexer.

Although the ESD protective circuit 114, the clamp circuit 116, the transmission gate 118 and the amplifier circuit 120 to be protected are located in the above-described example within the circuit 100, for example in a semiconductor chip, other components, for example the amplifier 108 and/or series resistor 110, may also be integrated in the circuit 100 in various exemplary embodiments.

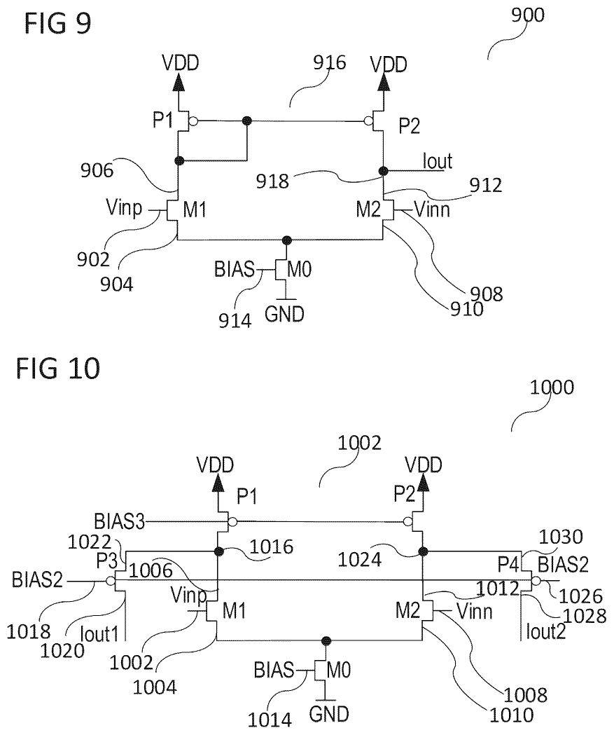

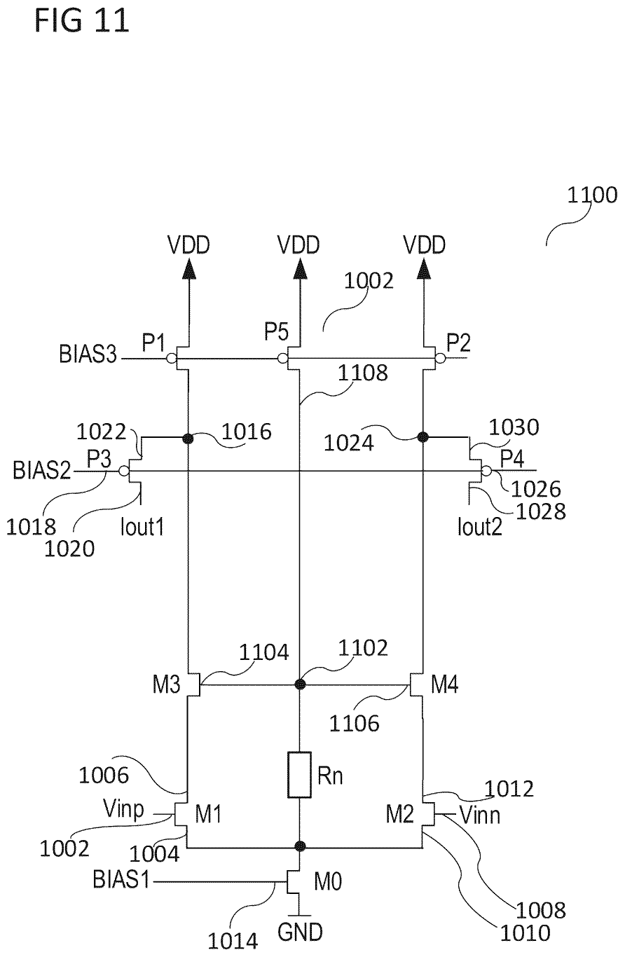

All architectures of the amplifier circuits from FIG. 9, FIG. 10 and FIG. 11 have the common feature that they do not function unconditionally at supply and input voltages higher than the rated voltage of the individual transistors. In such a scenario, the individual transistors may be damaged or even destroyed.

An example: At high input voltages, the third current source transistors M0 may have too high drain voltages. Inserting a cascode in which the gate is, for example, at half the supply voltage VDD/2 could solve this problem.

More problematic is the protection of the first transistor M1 and the second transistor M2 of the amplifier circuits 900, 1000, 1100 at low input voltages. An NMOS cascode transistor could be switched by means of the two transistors M1 and M2. However, if the input voltage is high, the first transistor M1 and the second transistor M2 would pass into the triode range and thus lose gain.

As an illustration, amplifier circuits in which a movable cascode voltage which resonates with the input signal or signals is provided are provided in accordance with various aspects of this disclosure.

As an illustration, in various aspects of this disclosure, in amplifier circuits (for example in the form of transconductance amplifiers), folded-cascode transistors of an input differential pair of transistors are actuated using a voltage derived from the (for example averaged) input voltages (wherein an input voltage is applied to each transistor of the input differential pair).

Various aspects also concern optional circuitry components, such as implementing a bypass path to the folded-cascode transistors to avoid interrupting the current path at extreme input voltage values.

A cascode may be understood as a circuit consisting of a transistor (for example a MOSFET), also referred to as a cascode transistor, with a voltage (for example a constant voltage) at the control terminal (for example gate) of the cascode transistor and an input current source connected to a controlled terminal (for example source) of the cascode transistor. A cascode stage typically consists of a transistor as a source circuit and a series-connected transistor in a gate circuit. The transistor in the source circuit is then no longer subject to the Miller effect. The Miller capacitance of the cascode transistor, in contrast, is so small that even a large voltage gain has no negative influence on the frequency response.

A folded cascode may be understood to mean a cascode in which a signal path in the amplifier circuit with a cascode transistor (for example PMOS cascode transistor) has both its beginning in a reference potential and its end in the same reference potential.

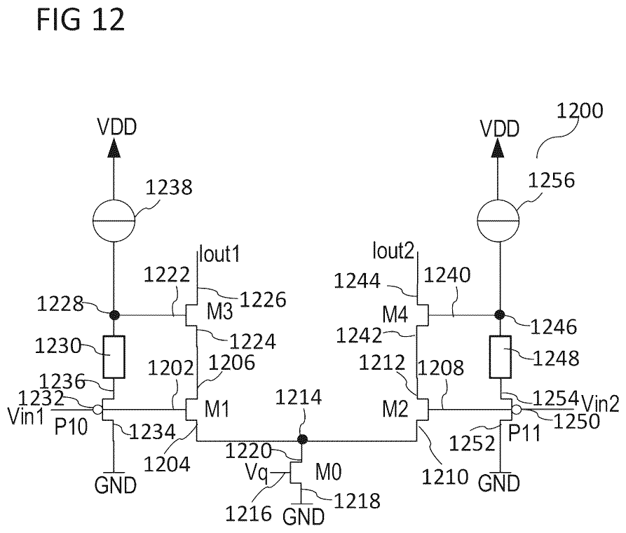

FIG. 12 shows an example of such a first amplifier circuit (as an example in the form of a transconductance amplifier) 1200, which will be explained in more detail below.

The first amplifier circuit 1200 may comprise a first transistor M1 and a second transistor M2. A first controlled terminal 1204 of the first transistor M1 is connected (for example directly) to a first controlled terminal 1210 of the second transistor M2, for example at a common first connection node 1214. A first current source, for example implemented by means of a first current source transistor M0, is connected between the first connection node 1214 and a first reference potential (for example ground potential GND), to the first controlled terminal 1218 of which the first reference potential is applied and the second controlled terminal 1220 of which is connected (for example directly) to the first connection node 1214. A source voltage Vq is applied to a control terminal 1216 of the first current source transistor M0.

The first transistor M1 and the second transistor M2 are of a first conductivity type (in this example of an n conductivity type). In other words, the first transistor M1 and the second transistor M2 are NMOS field-effect transistors (NMOS-FETs).

The first amplifier circuit 1200 may further comprise a third transistor M3 and a fourth transistor M4.

The third transistor M3 and the fourth transistor M4 are clearly cascode transistors. The third transistor M3 and the fourth transistor M4 are also of the first conductivity type, that is to say NMOS-FETs, for example.

The third transistor M3 is connected in series with the first transistor M1, wherein a first controlled terminal 1224 of the third transistor M3 is connected (for example directly) to a second controlled terminal 1206 of the first transistor M1. A first output current Iout1 is provided at a second controlled terminal 1226 of the third transistor M3. The third transistor M3 serves as a protective transistor for the first transistor M1.

The protection function for the first transistor M1 is provided by actuating a control terminal 1222 of the third transistor M3 in a certain way. The control terminal 1222 of the third transistor M3 is connected (for example directly) to a second connection node 1228. Furthermore, a first electrical (for example ohmic) resistor 1230 is provided, the first terminal of which is also connected (for example directly) to the second connection node 1228, and the second terminal of which is connected to a second controlled terminal 1236 of a fifth transistor P10. A first controlled terminal 1234 of the fifth transistor P10 is connected (for example directly) to a second reference potential (which may be equal to or different from the first reference potential). A first input voltage Vin1 (or a voltage dependent on the first input voltage Vin1) is applied to a control terminal 1232 of the fifth transistor P10. The first input voltage Vin1 (or a voltage dependent on the first input voltage Vin1) is also applied to the control terminal 1202 of the first transistor M1.

The fifth transistor P10 together with the third transistor M3 and the first resistor 1230 forms an example of a first circuit. The first circuit (M3, 1230 and P10) is connected on the input side to the second controlled terminal 1206 of the first transistor M1 and is controlled by a first voltage which depends on the first input voltage Vin1 which is applied to the control terminal 1202 of the first transistor M1 and which provides the first output current Iout1 on the output side.

Furthermore, a second current source 1238 is connected to the second connection node 1228.

As an illustration, the fifth transistor P10, the first resistor 1230 and the second current source 1238 at the second connection node 1228 replicate the first input voltage Vin1, but increased by a certain amount (for example 3 V). The same also applies to the node at the first controlled terminal 1224 of the third transistor M3. This also replicates the first input voltage Vin1 shifted by a certain voltage (for example 2.5 V). This results in the protection of the first transistor M1. However, the second connection node 1228 may not have a higher voltage than the supply voltage VDD. This means that if the first input voltage Vin1 is too high, the first transistor M1 may pass into the triode range.

The fourth transistor M4 is connected in series with the second transistor M2, wherein a first controlled terminal 1242 of the fourth transistor M4 is connected (for example directly) to a second controlled terminal 1212 of the second transistor M2. A second output current Iout2 is provided at a second controlled terminal 1244 of the fourth transistor M4. The fourth transistor M4 serves as a protective transistor for the second transistor M2.

The protection function for the second transistor M2 is provided by actuating a control terminal 1240 of the fourth transistor M4 in a certain way. The control terminal 1240 of the fourth transistor M4 is connected (for example directly) to a third connection node 1246. Furthermore, a second electrical (for example ohmic) resistor 1248 is provided, the first terminal of which is also connected (for example directly) to the third connection node 1246, and the second terminal of which is connected to a second controlled terminal 1254 of a sixth transistor P11. A first controlled terminal 1252 of the sixth transistor P11 is connected (for example directly) to a third reference potential (which may be equal to or different from the first reference potential). A second input voltage Vin2 (or a voltage dependent on the second input voltage Vin2) is applied to a control terminal 1250 of the sixth transistor P11. The second input voltage Vin2 (or a voltage dependent on the second input voltage Vin2) is also applied to the control terminal 1208 of the second transistor M2.

The sixth transistor P11 together with the fourth transistor M4 and the second resistor 1248 forms an example of a second circuit. The second circuit (M4, 1248 and P11) is connected on the input side to the second controlled terminal 1212 of the second transistor M2 and is controlled by a second voltage which depends on the second input voltage Vin2 which is applied to the control terminal 1208 of the second transistor M2 and which provides the second output current Iout2 on the output side.

Furthermore, a third current source 1256 is connected to the third connection node 1246.

As an illustration, the sixth transistor P11, the second resistor 1248 and the third current source 1256 at the third connection node 1246 replicate the second input voltage Vin2, but increased by a certain amount (for example 3 V). The same also applies to the node at the first controlled terminal 1242 of the fourth transistor M4. This also replicates the second input voltage Vin2 shifted by a certain voltage (for example 2.5 V). This results in the protection of the second transistor M2. However, the third connection node 1246 may not have a higher voltage than the supply voltage VDD. This means that if the first second voltage Vin2 is too high, the second transistor M2 may pass into the triode range.

The one at the control terminal 1222 of the third transistor M3 and the one at the control terminal 1240 of the fourth transistor M4 are independent of one another.

The individual transistors of the first amplifier circuit from FIG. 12 may also be replaced by a respective transistor of the opposite conductivity type (for example NMOS-FETs by PMOS-FETs and PMOS-FETs by NMOS-FETs). The corresponding reference potentials must then also be adapted accordingly (ground GND, for example, by VDD and VDD, for example, by ground GND).

The two cascode transistors above the first transistor M1 and the second transistor M2 (that is to say the third transistor M3 and the fourth transistor M4) could protect the first transistor M1 and the second transistor M2. However, at high input voltages Vin1, Vin2, the auxiliary transistors (fifth transistor P10 and sixth transistor P11), which are intended to generate the required bias voltages for the cascode transistors, should now have drain protection themselves.

PMOS cascode transistors which are biased at their drains at VDD/2 could be added.

Although this would protect these transistors (fifth transistor P10 and sixth transistor P11) at high input voltages Vin1, Vin2, at the same time the gate voltages at the third transistor M3 and at the fourth transistor M4 would increase to unacceptably high values at low input voltages Vin1, Vin2, which would lead to an unacceptably high load on the first transistor M1 and the second transistor M2.

FIG. 2 shows a second amplifier circuit 200 according to various aspects of the present disclosure which addresses the problem described above.

The second amplifier circuits 200 comprises a first transistor M1 and a second transistor M2. A first controlled terminal 204 (for example source) of the first transistor M1 is connected (for example directly) to a first controlled terminal 210 (for example source) of the second transistor M2. A second controlled terminal 206 (for example drain) of the first transistor M1 is connected to a second reference potential (for example a supply potential VDD) and a second controlled terminal 212 (for example drain) of the second transistor M2 is also connected to the second reference potential. A first input voltage Vin1 is applied to a control terminal 202 (for example gate) of the first transistor M1 and a second input voltage Vin2 is applied to a control terminal 208 (for example gate) of the second transistor M2.

The first transistor M1 and the second transistor M2 are of a first conductivity type, for example of an n conductivity type (for example NMOS-FETs).

The second amplifier circuit 200 further comprises a first circuit P3 (in this example formed by a third transistor P3) which is connected (for example directly) on the input side to the second controlled terminal 206 of the first transistor M1. For example, a second controlled terminal 218 of the third transistor P3 is connected (for example directly) to the second controlled terminal 206 of the first transistor M1. On the output side, the first circuit P3 provides a first output current Iout1, for example at a first controlled terminal 216 of the third transistor P3. Furthermore, the second amplifier circuit 200 has a first (for example voltage-controlled) voltage source 226 which controls the first circuit P3, for example by providing a first voltage 228 to a control terminal 214 of the third transistor P3. The first voltage source 226 generates the first voltage 228 depending on (in other words, as a function of) the first input voltage Vin1 which is applied to the control terminal 202 of the first transistor M1. The first voltage 228 may be lower than, equal to, or greater than the first input voltage Vin1.

The second amplifier circuit 200 further comprises a second circuit P4 (in this example formed by a fourth transistor P4) which is connected (for example directly) on the input side to the second controlled terminal 212 of the second transistor M2. For example, a second controlled terminal 224 of the fourth transistor P4 is connected (for example directly) to the second controlled terminal 212 of the second transistor M2. On the output side, the second circuit P4 provides a second output current Iout2, for example at a first controlled terminal 222 of the fourth transistor P4. Furthermore, the second amplifier circuit 200 has a second (for example voltage-controlled) voltage source 230 which controls the second circuit P4, for example by providing a first voltage 232 to a control terminal 220 of the fourth transistor P4. The second voltage source 230 generates the second voltage 232 depending on (in other words, as a function of) the second input voltage Vin2 which is applied to a control terminal 208 of the second transistor M2. The second voltage 232 may be lower than, equal to, or greater than the second input voltage Vin2.

The first circuit P3 and/or the second circuit P4 have a transistor (third transistor P3 or fourth transistor P4) of a second conductivity type, to the control terminal/control terminals of which the first voltage or the second voltage is applied. The second conductivity type is different from the first conductivity type, for example from a p conductivity type (for example, PMOS-FETs).

Furthermore, the second amplifier circuit 200 comprises a first current source 234 which is connected (for example directly) on the one hand to the first reference potential (for example ground potential GND) and on the other hand to the first controlled terminal 204 of the first transistor M1 and to the first controlled terminal 210 of the second transistor M2.

Furthermore, a second current source (formed for example by a first current source transistor 236 of the second conductivity type) and a third current source (formed for example by a second current source transistor 238 of the second conductivity type) are provided. A first controlled terminal 242 of the first current source transistor 236 is connected (for example directly) to the second controlled terminal 206 of the first transistor M1. A second controlled terminal 244 of the first current source transistor 236 is connected to the second reference potential, for example the supply voltage VDD. A third bias voltage BIAS3 is applied to a control terminal 240 of the first current source transistor 236. A first controlled terminal 248 of the second current source transistor 238 is connected (for example directly) to the second controlled terminal 212 of the second transistor M2. A second controlled terminal 250 of the second current source transistor 238 is connected to the second reference potential, for example the supply voltage VDD. The third bias voltage BIAS3 is also applied to a control terminal 246 of the second current source transistor 238.

As an illustration, the first circuit P3 and the second circuit P4 can be set up as folded-cascode devices (or folded-cascode transistors).

The first circuit P3 and the second circuit P4 are actuated by a respective voltage derived from the respective input voltage Vin1, Vin2.

The input voltages Vin1 and Vin2 control the control terminals 214 and 220 (for example the gates) of the third transistor P3 and the fourth transistor P4, respectively. In this way, the first controlled terminals 206, 212 (for example the drains) of the first transistor M1 and of the second transistor M2 or the corresponding drain-gate voltages can be protected against overvoltage.

The individual transistors in FIG. 2 may also be replaced by a respective transistor of the opposite conductivity type (for example NMOS-FETs by PMOS-FETs and PMOS-FETs by NMOS-FETs). The corresponding reference potentials must then also be adapted accordingly (the ground potential GND, for example, by the supply voltage VDD and the supply voltage VDD, for example, by the ground potential GND).

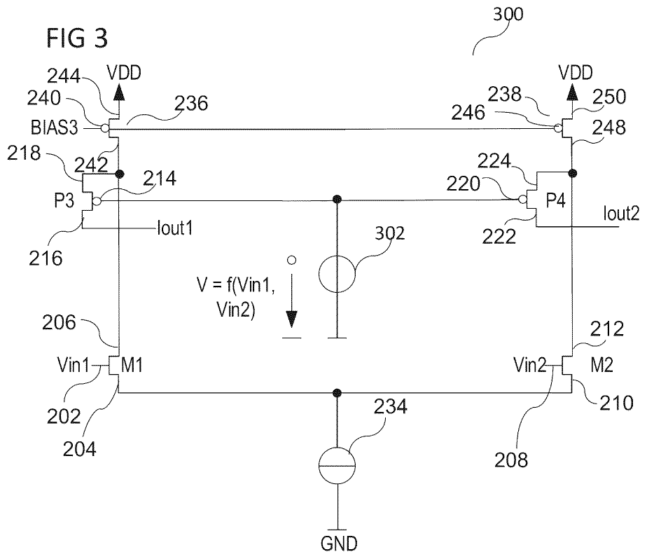

FIG. 3 shows a third amplifier circuit 300 according to various aspects of the present disclosure. The third amplifier circuit 300 is very similar to the second amplifier circuit 200 from FIG. 2, which is why only the differences between the two amplifier circuits 200, 300 will be discussed below. For all other components, reference is made to the above explanations regarding the second amplifier circuit 200.

In contrast to the second amplifier circuit 200, as an illustration, the two voltage sources of the second amplifier circuit 200 are combined to form a single (voltage-controlled) voltage source 302.

As an illustration, therefore, the first voltage source 226 and the second voltage source 230 in the second amplifier circuit 200 are replaced by a joint voltage source 302 in the third amplifier circuit 300, the joint voltage source being set up to provide the same voltage to the control terminal 214 of the third transistor P3 and to the control terminal 220 of the fourth transistor P4a, wherein the voltage depends on the first input voltage Vin1 which is applied to the control terminal 202 of the first transistor M1 and on the second input voltage Vin2 which is applied to the control terminal 208 of the second transistor M2.

The individual transistors in FIG. 3 may also be replaced by a respective transistor of the opposite conductivity type (for example NMOS-FETs by PMOS-FETs and PMOS-FETs by NMOS-FETs). The corresponding reference potentials must then also be adapted accordingly (the ground potential GND, for example, by the supply voltage VDD and the supply voltage VDD, for example, by the ground potential GND).

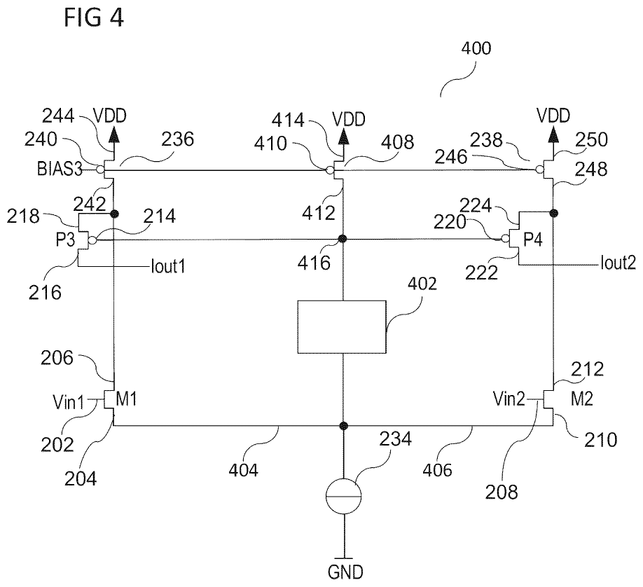

FIG. 4 shows a fourth amplifier circuit 400 according to various aspects of the present disclosure. The fourth amplifier circuit 400 is very similar to the third amplifier circuit 300 from FIG. 3, which is why only the differences between the two amplifier circuits 400, 300 will be discussed below. For all other components, reference is made to the above explanations regarding the second amplifier circuit 200 and the third amplifier circuit 300.

In the fourth amplifier circuit 400, a possible implementation of the joint voltage source 302 in the third amplifier circuit 300 is clearly indicated. Therefore, in order to realize the joint voltage source 302, there may be provision for a joint voltage source 402 which can be connected (for example directly) on the input side to the first controlled terminal 204 of the first transistor M1 and to the first controlled terminal 210 of the second transistor M2.

Furthermore, a fourth current source may be provided, for example formed by a third current source transistor 408 of the second conductivity type. The first controlled terminal 412 of the third current source transistor 408 is connected to an output of the joint voltage source 402. A second controlled terminal 414 of the third current source transistor 408 is connected to the supply voltage VDD. The third bias voltage BIAS3 is applied to a control terminal 410 of the third current source transistor 408. A voltage which is derived from a weighted average of the first input voltage Vin1 and the second input voltage Vin2 is produced at a node 416 (which is connected (for example directly) to an output of the joint voltage source 402 as well as to the control terminal 214 of the third transistor P3 and the control terminal 220 of the fourth transistor P3).

The individual transistors in FIG. 4 may also be replaced by a respective transistor of the opposite conductivity type (for example NMOS-FETs by PMOS-FETs and PMOS-FETs by NMOS-FETs). The corresponding reference potentials must then also be adapted accordingly (the ground potential GND, for example, by the supply voltage VDD and the supply voltage VDD, for example, by the ground potential GND).

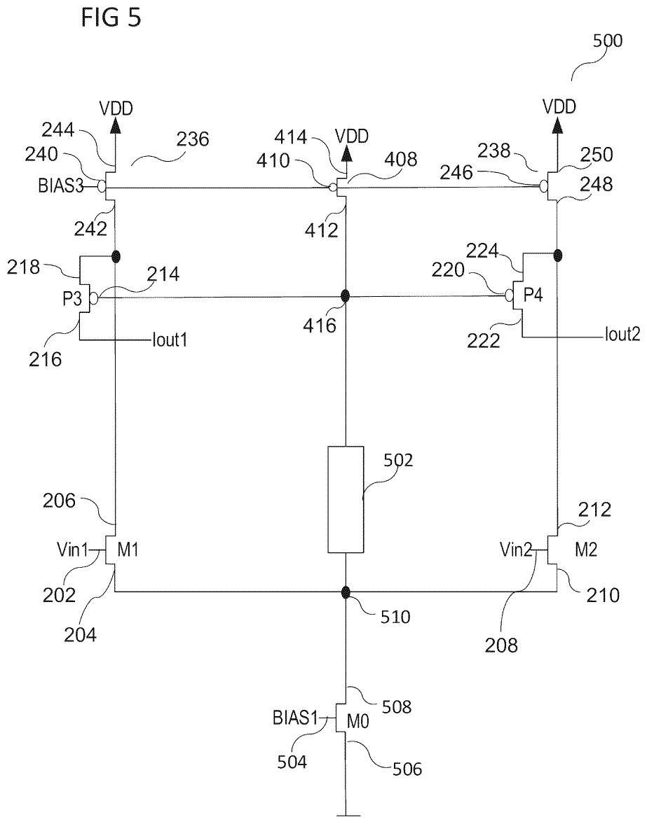

FIG. 5 shows a fifth amplifier circuit 500 according to various aspects of the present disclosure. The fifth amplifier circuit 500 is very similar to the fourth amplifier circuit 400 from FIG. 4, which is why only the differences between the two amplifier circuits 500, 400 will be discussed below. For all other components, reference is made to the above explanations regarding the second amplifier circuit 200, the third amplifier circuit 300 and the fourth amplifier circuit 400.

The joint voltage source 402 may be formed by one or more resistive electrical components 502, for example one or more electrical (for example ohmic) resistors 502 connected in series and/or one or more diodes connected in series (which may be implemented for example by means of diode-connected transistors). One or more resistors and one or more diodes may also be connected in series in the fifth amplifier circuit 500.

This allows additional MOS diodes to be used in series with the resistor 502. The resistor 502 could also be replaced by a MOS diode. The resistor 502 and/or the diode are/is used to shift the level.

Such a circuit could even work without a level shift. In this case, the additional branch in the middle could be omitted and the control terminal 214 (for example gate) of the third transistor P3 and the control terminal 220 (for example gate) of the fourth transistor P4 could be connected directly to the end node (sources of M1, M2), that is to say for example the control terminal 214 (for example gate) of the third transistor P3 directly to the control terminal 202 of the first transistor M1 and the control terminal 220 (for example gate) of the fourth transistor P4 directly to the control terminal 208 of the second transistor M2.

Furthermore, in the fifth amplifier circuit 500, a possible realization of the first current source 234 is illustrated by means of an additional current source transistor M0 of the first conductivity type, the first controlled terminal 506 of which is connected to the first reference potential (for example GND), the second controlled terminal 508 of which is connected to a first connection node 510, to which a terminal of the (for example 2-terminal) resistive electrical component 502, as well as the first controlled terminal 204 of the first transistor M1 and the first controlled terminal 210 of the second transistor M2 are also connected (for example directly).

Furthermore, there may be provision for the control terminal 214 of the third transistor P3 and the control terminal 220 of the fourth transistor P4 to be connected directly to the first connection node 510.

The individual transistors in FIG. 5 may also be replaced by a respective transistor of the opposite conductivity type (for example NMOS-FETs by PMOS-FETs and PMOS-FETs by NMOS-FETs). The corresponding reference potentials must then also be adapted accordingly (the ground potential GND, for example, by the supply voltage VDD and the supply voltage VDD, for example, by the ground potential GND).

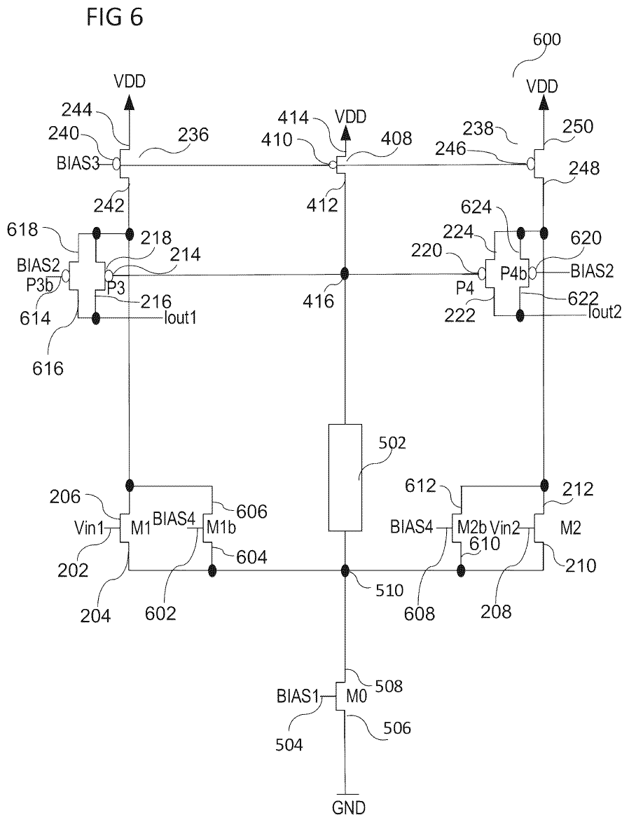

FIG. 6 shows a sixth amplifier circuit 600 according to various aspects of the present disclosure. The sixth amplifier circuit 600 is very similar to the fifth amplifier circuit 500 from FIG. 5, which is why only the differences between the two amplifier circuits 600, 500 will be discussed below. For all other components, reference is made to the above explanations regarding the second amplifier circuit 200, the third amplifier circuit 300, the fourth amplifier circuit 400 and the fifth amplifier circuit 500.

The components optionally additionally provided in the sixth amplifier circuit 600 may be provided each individually or in combination in the second amplifier circuit 200, in the third amplifier circuit 300 or in the fourth amplifier circuit 400 as well.

The sixth amplifier circuit 600 may also have various bypass paths, for example:
a first bypass path connected in parallel with the first transistor M1 and having a first bypass transistor M1b (of the first conductivity type), the control input 602 of which is set up to receive a fourth bias voltage BIAS4, the first controlled terminal 604 of which is connected (for example directly) to the first connection node 510 and the second controlled terminal 606 of which is connected (for example directly) to the second controlled terminal 206 of the first transistor M1; and/or
a second bypass path connected in parallel with the second transistor M2 and having a second bypass transistor M2b (of the first conductivity type), the control input 608 of which is also set up to receive the fourth bias voltage BIAS4, the first controlled terminal 610 of which is connected (for example directly) to the first connection node 510 and the second controlled terminal 612 of which is connected (for example directly) to the second controlled terminal 212 of the second transistor M2; and/or
a third bypass path connected in parallel with the third transistor P3 and having a third bypass transistor P3b (of the second conductivity type), the control input 614 of which is for receiving a second bias voltage BIAS2, the first controlled terminal 616 of which is connected (for example directly) to the first controlled terminal 216 of the third transistor P3 and the second controlled terminal 618 of which is connected (for example directly) to the second controlled terminal 218 of the third transistor P3; and/or
a fourth bypass path connected in parallel with the fourth transistor P4 and having a fourth bypass transistor P4b (of the second conductivity type), the control input 620 of which is set up to receive the second bias voltage BIAS2, the first controlled terminal 622 of which is connected (for example directly) to the first controlled terminal 222 of the fourth transistor P4 and the second controlled terminal 624 of which is connected (for example directly) to the second controlled terminal 224 of the fourth transistor P4.

The first bypass path and the second bypass path, which are connected to the fourth bias voltage BIAS4, are used to ensure a continuous flow of the tail current (provided by the first current source transistor M0), even if the input voltages Vin1 and Vin2 which are applied to the control terminal 202 of the first transistor M1 and at the control terminal 208 of the second transistor M2, respectively, are very low. Depending on the specific requirements, the first bypass path and the second bypass path may also be omitted.

The third bypass transistor P3b and the fourth bypass transistor P4b form bypass cascode transistors in the event that the input voltages Vin1 and Vin2 are very high and would therefore prevent the current flow through the third transistor P3 and the fourth transistor P4, respectively.

The individual transistors in FIG. 6 may also be replaced by a respective transistor of the opposite conductivity type (for example NMOS-FETs by PMOS-FETs and PMOS-FETs by NMOS-FETs). The corresponding reference potentials must then also be adapted accordingly (the ground potential GND, for example, by the supply voltage VDD and the supply voltage VDD, for example, by the ground potential GND).

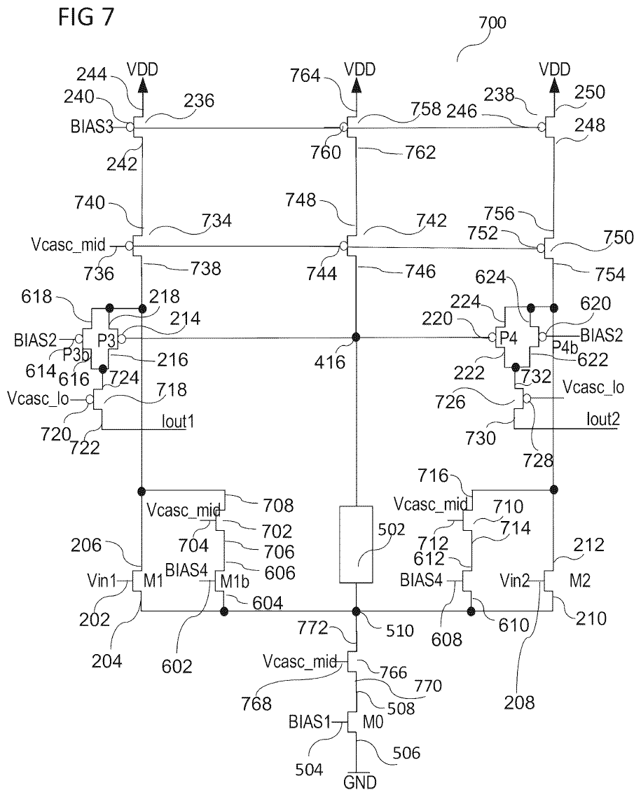

FIG. 7 shows a seventh amplifier circuit 700 according to various aspects of the present disclosure. The seventh amplifier circuit 700 is very similar to the sixth amplifier circuit 600 from FIG. 6, which is why only the differences between the two amplifier circuits 700, 600 will be discussed below. For all other components, reference is made to the above explanations regarding the second amplifier circuit 200, the third amplifier circuit 300, the fourth amplifier circuit 400, the fifth amplifier circuit 500 and the sixth amplifier circuit 600.

The seventh amplifier circuit 700 clearly provides a protected input stage.

The devices connected to control voltages Vcasc_lo, Vcasc_mid and Vcasc_hi, for example transistors, may be provided or omitted for further protection of various components of the amplifier circuit (for example the first to seventh amplifier circuit) depending on the specific voltage values and the properties of the device.

In the full example of the seventh amplifier circuit 700, these voltages VDD/2 (Vcasc_mid) and a diode drop are higher/lower than this (Vcasc_hi, Vcasc_lo).

The seventh amplifier circuit 700 may therefore have a first protective transistor 702 and a second protective transistor 710 (both of the first conductivity type).

A first control voltage Vcasc_mid can be applied to a control terminal 704 of the first protective transistor 702, a first controlled terminal 706 of the first protective transistor 702 can be connected (for example directly) to the second controlled terminal 606 of the first bypass transistor M1b and a second controlled terminal 708 of the first protective transistor 702 can be connected (for example directly) to the second controlled terminal 206 of the first transistor M1.

The first control voltage Vcasc_mid can also be applied to a control terminal 712 of the second protective transistor 710, a first controlled terminal 714 of the second protective transistor 710 can be connected (for example directly) to the second controlled terminal 612 of the second bypass transistor M2b and a second controlled terminal 716 of the second protective transistor 710 can be connected (for example directly) to the second controlled terminal 212 of the second transistor M2.

The seventh amplifier circuit 700 may also have a third protective transistor 718 and a fourth protective transistor 726 (both of the second conductivity type).

A second control voltage Vcasc_lo can be applied to a control terminal 720 of the third protective transistor 718, the first output current Iout1 can be provided at a first controlled terminal 722 of the third protective transistor 718 and a second controlled terminal 724 of the third protective transistor 718 can be connected (for example directly) to the first controlled terminal 216 of the third transistor P3.

The second control voltage Vcasc_lo can also be applied to a control terminal 728 of the fourth protective transistor 726, the second output current Iout2 can be provided at a first controlled terminal 730 of the fourth protective transistor 726 and a second controlled terminal 732 of the fourth protective transistor 726 can be connected (for example directly) to the first controlled terminal 222 of the fourth transistor P4.

As an alternative to or in addition to the protective transistors 702, 710, 718, 726, additional cascode transistors may be provided in the seventh amplifier circuit 700, for example a first cascode transistor 734, a second cascode transistor 742 and a third cascode transistor 750 (all of the second conductivity type).

The first control voltage Vcasc_mid can be applied to a control terminal 736 of the first cascode transistor 734, a first controlled terminal 738 of the first cascode transistor 734 can be connected (for example directly) to the second controlled terminal 206 of the first transistor transistor M1 and a second controlled terminal 740 of the first cascode transistor 734 can be connected (for example directly) to the first controlled terminal 242 of the first current source transistor 236.

The first control voltage Vcasc_mid can also be applied to a control terminal 744 of the second cascode transistor 742, a first controlled terminal 746 of the second cascode transistor 742 can be connected (for example directly) to the resistor 502, generally the joint voltage source, and a second controlled terminal 748 of the second cascode transistor 742 can be connected (for example directly) to a first controlled terminal 762 of a third current source transistor 758.

The first control voltage Vcasc_mid can furthermore be applied to a control terminal 752 of the third cascode transistor 750, a first controlled terminal 754 of the third cascode transistor 750 can be connected (for example directly) to the second controlled terminal 212 of the second transistor M2 and a second controlled terminal 756 of the third cascode transistor 750 can be connected (for example directly) to the first controlled terminal 248 of the second current source transistor 238.

The second current source may optionally comprise the third current source transistor 758 of the second conductivity type.

The first controlled terminal 762 of the third current source transistor 758 is connected (for example directly) to the second controlled terminal 748 of the second cascode transistor 742. A second controlled terminal 764 of the third current source transistor 758 is connected to the supply voltage VDD. The third bias voltage BIAS3 is applied to a control terminal 760 of the third current source transistor 758.

As an alternative to or in addition to the protective transistors 702, 710, 718, 726 and the cascode transistors 734, 742 and 750 of the amplifier circuit 700, a fifth protective transistor 766 may be provided to protect the additional current source transistor M0.

The fifth protective transistor 766 is connected in series with the additional current source transistor M0, between the second controlled terminal 508 of the additional current source transistor M0 and the first connection node 510. A control terminal 768 of the fifth protective transistor 766 is set up to receive a voltage, for example the voltage Vcasc_mid. A differential voltage between a voltage at the control terminal 504 of the additional current source transistor M0 (for example the first bias voltage BIAS1) and the received voltage (for example Vcasc_mid) is lower than the predetermined maximum voltage (for example the applicable operating voltage of the additional current source transistor M0).

A first controlled terminal 770 of the fifth protective transistor 766 is connected (for example directly) to the second controlled terminal 508 of the additional current source transistor M0 and a second controlled terminal 772 of the fifth protective transistor 766 is connected (for example directly) to the first connection node 510. In other words, the voltage Vcasc_mid is applied to the control terminal 768 of the fifth protective transistor 766, whereby the fifth protective transistor 766 is clearly used as a voltage limiter, which prevents voltages, for example at the gate oxide of the additional current source transistor M0, from becoming too great. The fifth protective transistor 766 ensures that such a voltage is applied to the second controlled terminal (for example drain) 508 of the additional current source transistor M0 that the magnitude of the gate-drain voltage at the additional current source transistor M0 is sufficiently low so that the additional current source transistor M0 (for example the gate oxide thereof) is not damaged.

The individual transistors in FIG. 7 may also be replaced by a respective transistor of the opposite conductivity type (for example NMOS-FETs by PMOS-FETs and PMOS-FETs by NMOS-FETs). The corresponding reference potentials must then also be adapted accordingly (the ground potential GND, for example, by the supply voltage VDD and the supply voltage VDD, for example, by the ground potential GND).

In the amplifier circuits described above, two respective output currents Iout1 and Iout2 are provided. If it is desired to form an output voltage from the two output currents Iout1 and Iout2, then different circuits may be used.

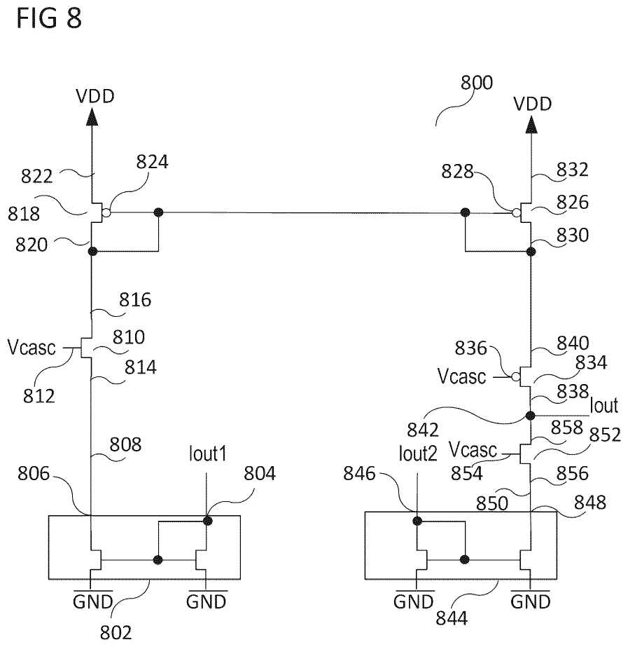

The circuit 800 shown in FIG. 8 is such an example, but of course other circuits can also be used for this purpose.

FIG. 8 shows the circuit 800 for generating a one-sided rail-to-rail output voltage Vout or a rail-to-rail output current Iout.

The two output currents Iout1 and Iout2 of the amplifier circuits 200, 300, 400, 500, 600, 700 from FIG. 2 to FIG. 7 described above can be clearly mirrored and combined into a joint output signal.

Vcasc is a cascode voltage which protects some current mirror transistors from overvoltage using some cascode devices. VDD/2 is a suitable voltage value for Vcasc.

The circuit 800 is an NMOS version of a folded-cascode amplifier core. If the circuit 800 is “inverted” and NMOS is replaced by PMOS and vice versa, it is possible to produce a PMOS version of such an amplifier core.

If the NMOS version and PMOS version of the respective amplifier circuits described above (amplifier circuits 200, 300, 400, 500, 600, 700, 1200) are connected in parallel and their output currents combined constructively, the result is a complete rail-to-rail amplifier.

The circuit 800 has a first current mirror 802 and a second current mirror 844. The first output current Iout1 is supplied to an input 804 of the first current mirror 802 and a mirrored first output current 808 is provided at an output 806 of the first current mirror 802. In this example, transistors of the first current mirror 802 and the second current mirror 844 are transistors of the first conductivity type.

The circuit 800 further comprises a first cascode transistor 810 (of the first conductivity type) and a first diode-connected transistor 818 (of the second conductivity type). The cascode voltage Vcasc is applied to a control terminal 812 of the cascode transistor 810, a first controlled terminal 814 of the cascode transistor 810 is connected (for example directly) to the output 806 of the first current mirror 802 and a second controlled terminal 816 of the cascode transistor 810 is connected (for example directly) to a first controlled terminal 820 (for example drain) of the first diode-connected transistor 818, the second controlled terminal 822 of which is connected for example to the supply voltage VDD.

The circuit 800 further comprises a second cascode transistor 834 (of the second conductivity type) and a second diode-connected transistor 826 (of the second conductivity type).

A control terminal 824 of the first diode-connected transistor 818 is connected (for example directly) to a control terminal 828 of the second diode-connected transistor 826, the second controlled terminal 832 of which is connected to the supply voltage VDD and the first controlled terminal 830 of which is connected (for example directly) to a second controlled terminal 840 of the second cascode transistor 834.

The cascode voltage Vcasc is also applied to a control terminal 836 of the second cascode transistor 834. A first controlled terminal 838 is connected (for example directly) to an output node 842.

The second output current Iout2 is supplied to an input 846 of the second current mirror 844 and a mirrored second output current 850 is provided at an output 848 of the second current mirror 844.

Furthermore, a third cascode transistor 852 (of the first conductivity type) is provided, to the third control terminal 854 of which the cascode voltage Vcasc is applied, the first controlled terminal 856 of which is connected (for example directly) to the output 848 of the second current mirror 844 and the second controlled terminal 858 of which is connected (for example directly) to the output node 842.

An output voltage Vout or an output current Iout is therefore provided at the output node 842, these being dependent on the first output current Iout1 and the second output current Iout2.

The various transistors of the amplifier circuits illustrated above (for example first to seventh amplifier circuit) may each be set up as laterally diffused metal-oxide semiconductor (LDMOS) transistor.

The following text explains various aspects of the disclosure:

Example 1 is an amplifier circuit. The amplifier circuit may comprise a first transistor and a second transistor, the first controlled terminals of which are connected to one another and to a first reference potential, and the second controlled terminals of which are connected to a second reference potential. The first transistor and the second transistor are of a first conductivity type. The amplifier circuit may further comprise a first circuit connected on the input side to the second controlled terminal of the first transistor and controlled by a first voltage which depends on a first input voltage which is applied to a control terminal of the first transistor and which provides a first output current on the output side, and a second circuit connected on the input side to the second controlled terminal of the second transistor and controlled by a second voltage which depends on a second input voltage which is applied to a control terminal of the second transistor and which provides a second output current on the output side. The first circuit and/or the second circuit has a transistor of a second conductivity type, to the control terminal of which the first voltage or the second voltage is applied, wherein the second conductivity type is different from the first conductivity type.

In example 2, the subject matter of example 1 may optionally comprise the first circuit having a third transistor as the transistor of a second conductivity type, the first controlled terminal of which is connected to the second controlled terminal of the first transistor, the control terminal of which is set up to receive the first voltage, and the second controlled terminal of which provides the first output current.

In example 3, the subject matter of any of examples 1 or 2 may optionally comprise the second circuit having a fourth transistor as the transistor of a second conductivity type, the first controlled terminal of which is connected to the second controlled terminal of the second transistor, the control terminal of which is set up to receive the second voltage, and the second controlled terminal of which provides the second output current.

In example 4, the subject matter of any of examples 1 to 3 may optionally comprise the amplifier circuit further comprising a first voltage source which is connected to the first circuit for providing the first voltage which depends on the first input voltage which is applied to the control terminal of the first transistor.

In example 5, the subject matter of any of examples 1 to 4 may optionally comprise the amplifier circuit further comprising a second voltage source which is connected to the second circuit for providing the first voltage which depends on the second input voltage which is applied to the control terminal of the second transistor.

In example 6, the subject matter of any of examples 4 or 5 may optionally comprise the first voltage source and the second voltage source forming a joint voltage source which is set up to provide the same voltage to the circuit as the first voltage and to the second circuit as the second voltage, wherein the same voltage depends on the first input voltage which is applied to the control terminal of the first transistor and on the second input voltage which is applied to the control terminal of the second transistor.

In example 7, the subject matter of example 6 may optionally comprise the joint voltage source having a resistive electrical component.

In example 8, the subject matter of example 7 may optionally comprise the resistive electrical component having a diode and/or an electrical ohmic resistor.

In example 9, the subject matter of any of examples 1 to 8 may optionally comprise the amplifier circuit furthermore comprising a first current source which provides current to the first controlled terminal of the first transistor and/or the first controlled terminal of the second transistor.

In example 10, the subject matter of example 9 may optionally comprise the first current source having a first current source transistor which is connected between the first controlled terminal of the first transistor and the first reference potential and the control input of which is set up to receive a first bias voltage.

In example 11, the subject matter of example 10 may optionally comprise the amplifier circuit further comprising a first protective circuit which is connected in series with the first current source transistor, between the first controlled terminal of the first transistor and the first current source transistor, wherein the first protective circuit is set up in such a way that a voltage difference between the control terminal of the first current source transistor and the second controlled terminal of the first transistor is lower than a predetermined maximum voltage.

In example 12, the subject matter of example 11 may optionally comprise the first protective circuit comprising a first protective transistor which is connected in series with the first current source transistor, between the first controlled terminal of the first transistor and the first current source transistor, wherein a control terminal of the first protective circuit is set up to receive the voltage, wherein a differential voltage between a voltage at the control terminal of the first current source transistor and the received voltage is lower than the predetermined maximum voltage.

In example 13, the subject matter of any of examples 1 to 12 may optionally comprise the amplifier circuit further comprising a first bypass path connected in parallel with the first transistor and having a first bypass transistor, the control input of which is set up to receive a second bias voltage.

In example 14, the subject matter of example 13 may optionally comprise the first bypass path further comprising a second bypass transistor, the control input of which is set up to receive a voltage, wherein a differential voltage between a voltage at the control terminal of the first bypass transistor and the received voltage is lower than the predetermined maximum voltage.

In example 15, the subject matter of any of examples 1 to 14 may optionally comprise the amplifier circuit further comprising a second bypass path connected in parallel with the second transistor and having a third bypass transistor, the control input of which is set up to receive a third bias voltage.

In example 16, the subject matter of example 15 may optionally comprise the second bypass path further comprising a fourth bypass transistor, the control input of which is set up to receive a voltage, wherein a differential voltage between a voltage at the control terminal of the third bypass transistor and the received voltage is lower than the predetermined maximum voltage.

In example 17, the subject matter of any of examples 2 to 16 may optionally comprise the amplifier circuit further comprising a third bypass path connected in parallel with the third transistor and having a fifth bypass transistor, the control input of which is set up to receive a fourth bias voltage.

In example 18, the subject matter of example 17 may optionally comprise the third bypass path further comprising a sixth bypass transistor, the control input of which is set up to receive a voltage, wherein a differential voltage between a voltage at the control terminal of the fifth bypass transistor and the received voltage is lower than the predetermined maximum voltage.

In example 19, the subject matter of any of examples 3 to 18 may optionally comprise the amplifier circuit further comprising a fourth bypass path connected in parallel with the fourth transistor and having a seventh bypass transistor, the control input of which is set up to receive a fifth bias voltage.

In example 20, the subject matter of example 19 may optionally comprise the fourth bypass path further comprising an eighth bypass transistor, the control input of which is set up to receive a voltage, wherein a differential voltage between a voltage at the control terminal of the second bypass transistor and the received voltage is lower than the predetermined maximum voltage.

In example 21, the subject matter of any of examples 1 to 20 may optionally comprise the amplifier circuit furthermore comprising a second current source which is connected between the second terminal of the first transistor and the second reference potential.

In example 22, the subject matter of example 21 may optionally comprise the second current source having a second current source transistor which is connected between the second terminal of the first transistor and the second reference potential and the control input of which is set up to receive a sixth bias voltage.

In example 23, the subject matter of either of examples 21 and 22 may optionally comprise the amplifier circuit further comprising a second protective circuit which is connected in series with the second current source transistor, between the second controlled terminal of the first transistor and the second current source, wherein the second protective circuit is set up in such a way that a voltage difference between the control terminal of the second current source transistor and the first controlled terminal of the first transistor is lower than a predetermined maximum voltage.

In example 24, the subject matter of example 23 may optionally comprise the second protective circuit comprising a second protective transistor which is connected in series with the second current source transistor, between the second controlled terminal of the first transistor and the second current source, wherein a control terminal of the second protective transistor is set up to receive a voltage, wherein a differential voltage between a voltage at the control terminal of the second current source transistor and the received voltage is lower than the predetermined maximum voltage.

In example 25, the subject matter of any of examples 1 to 24 may optionally comprise the amplifier circuit furthermore comprising a third current source which is connected between the second terminal of the second transistor and the second reference potential.

In example 26, the subject matter of example 25 may optionally comprise the third current source having a third current source transistor which is connected between the second terminal of the second transistor and the second reference potential and the control input of which is set up to receive a seventh bias voltage.

In example 27, the subject matter of either of examples 25 and 26 may optionally comprise the amplifier circuit further comprising a third protective circuit which is connected in series with the third current source, between the second controlled terminal of the second transistor and the third current source, wherein the third protective circuit is set up in such a way that a voltage difference between the control terminal of the third current source transistor and the first controlled terminal of the first transistor is lower than a predetermined maximum voltage.

In example 28, the subject matter of example 27 may optionally comprise the third protective circuit comprising a third protective transistor which is connected in series with the third current source, between the second controlled terminal of the second transistor and the third current source, wherein a control terminal of the third protective transistor is set up to receive a voltage, wherein a differential voltage between a voltage at the control terminal of the third current source transistor and the received voltage is lower than the predetermined maximum voltage.

In example 29, the subject matter of any of examples 11 to 25 may optionally comprise the predetermined maximum voltage being equal to or lower than an applicable operating voltage of the first transistor.

In example 30, the subject matter of example 29 may optionally comprise the predetermined maximum voltage being in the range of from 1.5 V to 4 V.

In example 31, the subject matter of any of examples 1 to 30 may optionally comprise the first transistor and/or the second transistor being arranged as a laterally diffused metal-oxide semiconductor transistor.

In example 32, the subject matter of any of examples 1 to 31 may optionally comprise a voltage difference between the first input voltage and the first reference potential being greater than an applicable operating voltage of the first transistor, and/or wherein a voltage difference between the second input voltage and the first reference potential is greater than an applicable operating voltage of the second transistor.

In example 33, the subject matter of any of examples 1 to 32 may optionally comprise the amplifier circuit furthermore comprising a circuit which provides a total output current which is dependent on the first output current and the second output current.

Example 34 is a circuit. The circuit may comprise an amplifier circuit according to one of examples 1 to 33 and an analog-to-digital converter downstream of the amplifier circuit.

In example 35, the subject matter of example 34 may optionally comprise the circuit further comprising a logic circuit downstream of the analog-to-digital converter.

In example 36, the subject matter of example 35 may optionally comprise the logic circuit being a microcontroller.

In example 37, the subject matter of any of examples 34 to 36 may optionally comprise the circuit further comprising a sensor circuit having at least one sensor, wherein the amplifier circuit is connected between the sensor circuit and the analog-to-digital converter.

Example 38 is an amplifier circuit. The amplifier circuit may comprise a first transistor and a second transistor, the first controlled terminals of which are connected to one another and to a first reference potential, and the second controlled terminals of which are connected to a second reference potential, wherein the first transistor and the second transistor are of a first conductivity type. The amplifier circuit may furthermore comprise a third transistor, the first controlled terminal of which is connected to the second controlled terminal of the first transistor, the control terminal of which is set up to receive a voltage which depends on a first input voltage which is applied to a control terminal of the first transistor, and the second controlled terminal of which provides a first output current. The amplifier circuit may furthermore comprise a fourth transistor, the first controlled terminal of which is connected to the second controlled terminal of the second transistor, the control terminal of which is set up to receive a voltage which depends on a second input voltage which is applied to a control terminal of the second transistor, and the second controlled terminal of which provides a second output current. The third transistor and the fourth transistor are of a second conductivity type which is different from the first conductivity type.

In example 39, the subject matter of example 38 may optionally comprise the amplifier circuit further comprising a first voltage source which is connected to the control terminal of the third transistor and is set up to provide the voltage to the control terminal of the third transistor, said voltage depending on the first input voltage which is applied to a control terminal of the first transistor.

In example 40, the subject matter of either of examples 38 and 39 may optionally comprise the amplifier circuit further comprising a second voltage source which is connected to the control terminal of the fourth transistor and is set up to provide the voltage to the control terminal of the fourth transistor, said voltage depending on the second input voltage which is applied to a control terminal of the second transistor.

In example 41, the subject matter of either of examples 39 and 40 may optionally comprise the first voltage source and the second voltage source forming a joint voltage source which is set up to provide the same voltage to the control terminal of the third transistor and to the control terminal of the fourth transistor, wherein the voltage depends on the first input voltage which is applied to a control terminal of the first transistor and on the second input voltage which is applied to a control terminal of the second transistor.

In example 42, the subject matter of example 41 may optionally comprise the joint voltage source having a resistive electrical component.

In example 43, the subject matter of example 42 may optionally comprise the resistive electrical component having a diode and/or an electrical ohmic resistor.

In example 44, the subject matter of any of examples 38 to 43 may optionally comprise the amplifier circuit furthermore comprising a first current source which provides power to the first controlled terminal of the first transistor and/or the first controlled terminal of the second transistor.

In example 45, the subject matter of example 44 may optionally comprise the first current source having a first current source transistor which is connected between the first controlled terminal of the first transistor and the first reference potential and the control input of which is set up to receive a first bias voltage.

In example 46, the subject matter of either of examples 44 and 45 may optionally comprise the amplifier circuit further comprising a first protective circuit which is connected in series with the first current source, between the first controlled terminal of the first transistor and the first current source, wherein the first protective circuit is set up in such a way that a voltage difference between the control terminal of the first current source transistor and the second controlled terminal of the first transistor is lower than a predetermined maximum voltage.

In example 47, the subject matter of example 46 may optionally comprise the first protective circuit comprising a first protective transistor which is connected in series with the first current source transistor, between the first controlled terminal of the first transistor and the first current source transistor, wherein a control terminal of the first protective circuit is set up to receive the voltage, wherein a differential voltage between a voltage at the control terminal of the first current source transistor and the received voltage is lower than the predetermined maximum voltage.

In example 48, the subject matter of any of examples 38 to 47 may optionally comprise the amplifier circuit further comprising a first bypass path connected in parallel with the first transistor and having a first bypass transistor, the control input of which is set up to receive a second bias voltage.

In example 49, the subject matter of example 48 may optionally comprise the first bypass path further comprising a second bypass transistor, the control input of which is set up to receive a voltage, wherein a differential voltage between a voltage at the control terminal of the first bypass transistor and the received voltage is lower than the predetermined maximum voltage.

In example 50, the subject matter of any of examples 38 to 49 may optionally comprise the amplifier circuit further comprising a second bypass path connected in parallel with the second transistor and having a third bypass transistor, the control input of which is set up to receive a third bias voltage.

In example 51, the subject matter of example 50 may optionally comprise the second bypass path further comprising a fourth bypass transistor, the control input of which is set up to receive a voltage, wherein a differential voltage between a voltage at the control terminal of the third bypass transistor and the received voltage is lower than the predetermined maximum voltage.

In example 52, the subject matter of any of examples 38 to 51 may optionally comprise the amplifier circuit further comprising a third bypass path connected in parallel with the third transistor and having a fifth bypass transistor, the control input of which is set up to receive a fourth bias voltage.

In example 53, the subject matter of example 52 may optionally comprise the third bypass path further comprising a sixth bypass transistor, the control input of which is set up to receive a voltage, wherein a differential voltage between a voltage at the control terminal of the fifth bypass transistor and the received voltage is lower than the predetermined maximum voltage.

In example 54, the subject matter of any of examples 38 to 53 may optionally comprise the amplifier circuit further comprising a fourth bypass path connected in parallel with the fourth transistor and having a seventh bypass transistor, the control input of which is set up to receive a fifth bias voltage.

In example 55, the subject matter of example 54 may optionally comprise the fourth bypass path further comprising an eighth bypass transistor, the control input of which is set up to receive a voltage, wherein a differential voltage between a voltage at the control terminal of the second bypass transistor and the received voltage is lower than the predetermined maximum voltage.

In example 56, the subject matter of any of examples 38 to 55 may optionally comprise the amplifier circuit furthermore comprising a second current source which is connected between the second terminal of the first transistor and the second reference potential.

In example 57, the subject matter of example 56 may optionally comprise the second current source having a second current source transistor which is connected between the second terminal of the first transistor and the second reference potential and the control input of which is set up to receive a sixth bias voltage.

In example 58, the subject matter of either of examples 56 and 57 may optionally comprise the amplifier circuit further comprising a second protective circuit which is connected in series with the second current source transistor, between the second controlled terminal of the first transistor and the second current source, wherein the second protective circuit is set up in such a way that a voltage difference between the control terminal of the second current source transistor and the first controlled terminal of the first transistor is lower than a predetermined maximum voltage.

In example 59, the subject matter of example 58 may optionally comprise the second protective circuit comprising a second protective transistor which is connected in series with the second current source transistor, between the second controlled terminal of the first transistor and the second current source, wherein a control terminal of the second protective transistor is set up to receive a voltage, wherein a differential voltage between a voltage at the control terminal of the second current source transistor and the received voltage is lower than the predetermined maximum voltage.

In example 60, the subject matter of any of examples 38 to 59 may optionally comprise the amplifier circuit furthermore comprising a third current source which is connected between the second terminal of the second transistor and the second reference potential.

In example 61, the subject matter of example 60 may optionally comprise the third current source having a third current source transistor which is connected between the second terminal of the second transistor and the second reference potential and the control input of which is set up to receive a seventh bias voltage.

In example 62, the subject matter of either of examples 60 and 61 may optionally comprise the amplifier circuit further comprising a third protective circuit which is connected in series with the third current source, between the second controlled terminal of the second transistor and the third current source, wherein the third protective circuit is set up in such a way that a voltage difference between the control terminal of the third current source transistor and the first controlled terminal of the first transistor is lower than a predetermined maximum voltage.

In example 63, the subject matter of example 62 may optionally comprise the third protective circuit comprising a third protective transistor which is connected in series with the third current source, between the second controlled terminal of the second transistor and the third current source, wherein a control terminal of the third protective transistor is set up to receive a voltage, wherein a differential voltage between a voltage at the control terminal of the third current source transistor and the received voltage is lower than the predetermined maximum voltage.

In example 64, the subject matter of any of examples 48 to 63 may optionally comprise the predetermined maximum voltage being equal to or lower than an applicable operating voltage of the first transistor.

In example 65, the subject matter of example 64 may optionally comprise the predetermined maximum voltage being in the range of from 1.5 V to 4 V.

In example 66, the subject matter of any of examples 38 to 65 may optionally comprise the first transistor and/or the second transistor being arranged as a laterally diffused metal-oxide semiconductor transistor.

In example 67, the subject matter of any of examples 38 to 66 may optionally comprise a voltage difference between the first input voltage and the first reference potential being greater than an applicable operating voltage of the first transistor, and/or wherein a voltage difference between the second input voltage and the first reference potential is greater than an applicable operating voltage of the second transistor.

In example 68, the subject matter of any of examples 38 to 67 may optionally comprise the amplifier circuit furthermore comprising a circuit which provides a total output current which is dependent on the first output current and the second output current.

Example 69 is a circuit. The circuit may comprise an amplifier circuit according to one of examples 38 to 68 and an analog-to-digital converter downstream of the amplifier circuit.

In example 70, the subject matter of example 69 may optionally comprise the circuit further comprising a logic circuit downstream of the analog-to-digital converter.

In example 71, the subject matter of example 70 may optionally comprise the logic circuit being a microcontroller.

In example 72, the subject matter of any of examples 69 to 71 may optionally comprise the circuit further comprising a sensor circuit having at least one sensor, wherein the amplifier circuit is connected between the sensor circuit and the analog-to-digital converter.

Example 73 is an amplifier circuit. The amplifier circuit may comprise a pair of input differential transistors, at least one pair of folded-cascode transistors, the conductivity type of which is different from the conductivity type of the input differential transistors, wherein each controlled terminal of a transistor of the pair of input differential transistors is connected to a controlled terminal of an associated transistor of the pair of folded-cascode transistors, and wherein each control terminal of a transistor of the pair of folded-cascode transistors is set up to receive a voltage which depends on a respective input voltage which is applied to a control terminal of an associated transistor of the pair of input differential transistors.

In example 74, the subject matter of example 73 may optionally comprise the amplifier circuit further comprising a voltage source which is connected to the control terminal of each transistor of the pair of folded-cascode transistors and is set up to provide the voltage to each transistor of the pair of folded-cascode transistors, said voltage depending on a respective input voltage which is applied to a control terminal of an associated transistor of the pair of input differential transistors.

In example 75, the subject matter of either of examples 73 and 74 may optionally comprise the voltage source having a resistive electrical component.

In example 76, the subject matter of example 75 may optionally comprise the resistive electrical component having a diode and/or an electrical ohmic resistor.

In example 77, the subject matter of any of examples 73 to 76 may optionally comprise the amplifier circuit furthermore comprising a first current source which provides power to a first controlled terminal of each transistor of the pair of input differential transistors.

In example 78, the subject matter of example 77 may optionally comprise the first current source having a first current source transistor which is connected between the first controlled terminal of each transistor of the pair of input differential transistors and the control input of which is set up to receive a first bias voltage.

In example 79, the subject matter of either of examples 77 and 78 may optionally comprise the amplifier circuit further comprising a first protective circuit which is connected in series with the first current source, between the first controlled terminal of each transistor of the pair of input differential transistors and the first current source, wherein the first protective circuit is set up in such a way that a voltage difference between the control terminal of the first current source transistor and the respective second controlled terminal of the pair of input differential transistors is lower than a predetermined maximum voltage.

In example 80, the subject matter of example 79 may optionally comprise the first protective circuit comprising a first protective transistor which is connected in series with the first current source, between the first controlled terminal of each transistor of the pair of input differential transistors and the first current source, wherein a control terminal of the first protective transistor is set up to receive the voltage, wherein a differential voltage between a voltage at the control terminal of the first current source transistor and the received voltage is lower than the predetermined maximum voltage.

In example 81, the subject matter of any of examples 73 to 80 may optionally comprise the amplifier circuit further comprising a first bypass path connected in parallel with the first transistor of the pair of input differential transistors and having a first bypass transistor, the control input of which is set up to receive a second bias voltage.

In example 82, the subject matter of example 81 may optionally comprise the first bypass path further comprising a second bypass transistor, the control input of which is set up to receive a voltage, wherein a differential voltage between a voltage at the control terminal of the first bypass transistor and the received voltage is lower than the predetermined maximum voltage.

In example 83, the subject matter of any of examples 73 to 82 may optionally comprise the amplifier circuit further comprising a second bypass path connected in parallel with a second transistor of the pair of input differential transistors and having a third bypass transistor, the control input of which is set up to receive a third bias voltage.

In example 84, the subject matter of example 83 may optionally comprise the second bypass path further comprising a fourth bypass transistor, the control input of which is set up to receive a voltage, wherein a differential voltage between a voltage at the control terminal of the third bypass transistor and the received voltage is lower than the predetermined maximum voltage.

In example 85, the subject matter of any of examples 73 to 84 may optionally comprise the amplifier circuit further comprising a third bypass path connected in parallel with a first transistor of the pair of folded-cascode transistors and having a fifth bypass transistor, the control input of which is set up to receive a fourth bias voltage.

In example 86, the subject matter of example 85 may optionally comprise the third bypass path further comprising a sixth bypass transistor, the control input of which is set up to receive a voltage, wherein a differential voltage between a voltage at the control terminal of the fifth bypass transistor and the received voltage is lower than the predetermined maximum voltage.

In example 87, the subject matter of any of examples 73 to 86 may optionally comprise the amplifier circuit further comprising a fourth bypass path connected in parallel with a second transistor of the pair of folded-cascode transistors and having a seventh bypass transistor, the control input of which is set up to receive a fifth bias voltage.

In example 88, the subject matter of example 87 may optionally comprise the fourth bypass path further comprising an eighth bypass transistor, the control input of which is set up to receive a voltage, wherein a differential voltage between a voltage at the control terminal of the second bypass transistor and the received voltage is lower than the predetermined maximum voltage.

In example 89, the subject matter of any of examples 73 to 88 may optionally comprise the amplifier circuit furthermore comprising a second current source which is connected between the second terminal of a first transistor of the pair of input differential transistors and the second reference potential.

In example 90, the subject matter of example 89 may optionally comprise the second current source having a second current source transistor which is connected between the second terminal of the first transistor of the pair of input differential amplifiers and the second reference potential, and the control input of which is set up to receive a sixth bias voltage.

In example 91, the subject matter of either of examples 89 and 90 may optionally comprise the amplifier circuit further comprising a second protective circuit which is connected in series with the second current source, between the second controlled terminal of the first transistor of the pair of input differential transistors and the second current source, wherein the second protective circuit is set up in such a way that a voltage difference between the control terminal of the second current source transistor and the first controlled terminal of the first transistor is lower than a predetermined maximum voltage.

In example 92, the subject matter of example 91 may optionally comprise the second protective circuit comprising a second protective transistor which is connected in series with the second current source transistor, between the second controlled terminal of the first transistor of the pair of input differential transistors and the second current source, wherein a control terminal of the second protective transistor is set up to receive a voltage, wherein a differential voltage between a voltage at the control terminal of the second current source transistor and the received voltage is lower than the predetermined maximum voltage.

In example 93, the subject matter of any of examples 73 to 92 may optionally comprise the amplifier circuit furthermore comprising a third current source which is connected between the second terminal of a second transistor of the pair of input differential transistors and the second reference potential.

In example 94, the subject matter of example 93 may optionally comprise the third current source having a third current source transistor which is connected between the second terminal of the second transistor of the pair of input differential transistors and the second reference potential and the control input of which is set up to receive a seventh bias voltage.

In example 95, the subject matter of either of examples 93 and 94 may optionally comprise the amplifier circuit further comprising a third protective circuit which is connected in series with the third current source, between the second controlled terminal of the second transistor of the pair of input differential transistors and the third current source, wherein the third protective circuit is set up in such a way that a voltage difference between the control terminal of the third current source transistor and the first controlled terminal of the first transistor is lower than a predetermined maximum voltage.

In example 96, the subject matter of example 95 may optionally comprise the third protective circuit comprising a third protective transistor which is connected in series with the third current source, between the second controlled terminal of the second transistor of the pair of input differential transistors and the third current source, wherein a control terminal of the third protective transistor (P2n) is set up to receive a voltage, wherein a differential voltage between a voltage at the control terminal of the third current source transistor and the received voltage is lower than the predetermined maximum voltage.

In example 97, the subject matter of any of examples 73 to 96 may optionally comprise a voltage difference between the first input voltage and the first reference potential being greater than an applicable operating voltage of the first transistor of the pair of input differential transistors.

In example 98, the subject matter of any of examples 73 to 97 may optionally comprise the predetermined maximum voltage being equal to or lower than an applicable operating voltage of the first transistor.

In example 99, the subject matter of example 98 may optionally comprise the predetermined maximum voltage being in the range of from 1.5 V to 4 V.

In example 100, the subject matter of any of examples 73 to 99 may optionally comprise the first transistor and/or the second transistor being arranged as a laterally diffused metal-oxide semiconductor transistor.

In example 101, the subject matter of any of examples 73 to 100 may optionally comprise the amplifier circuit further comprising a circuit which provides a total output current which is dependent on a first output current which is provided by a first transistor of the pair of folded-cascode transistors and which is further dependent on a second output current which is provided by a second transistor of the pair of folded-cascode transistors.

Example 102 is a circuit. The circuit may comprise an amplifier circuit according to one of examples 73 to 101 and an analog-to-digital converter downstream of the amplifier circuit.

In example 103, the subject matter of example 102 may optionally comprise the circuit further comprising a logic circuit downstream of the analog-to-digital converter.

In example 104, the subject matter of example 103 may optionally comprise the logic circuit being a microcontroller.

In example 105, the subject matter of any of examples 102 to 104 may optionally comprise the circuit further comprising a sensor circuit having at least one sensor, wherein the amplifier circuit is connected between the sensor circuit and the analog-to-digital converter.

Example 106 is an amplifier circuit. The amplifier circuit may comprise a first transistor and a second transistor, the first controlled terminals of which are connected to one another and to a first reference potential, and a first circuit connected on the input side to the second controlled terminal of the first transistor and controlled by a first voltage which depends on a first input voltage which is applied to a control terminal of the first transistor and which provides a first output current on the output side. The amplifier circuit may furthermore comprise a second circuit, connected on the input side to the second controlled terminal of the second transistor and controlled by a second voltage which depends on a second input voltage which is applied to a control terminal of the second transistor and which provides a second output current on the output side. The first voltage is independent of the second voltage.

What is claimed is:

1. An amplifier circuit, comprising:
a first transistor having a control terminal and first and second controlled terminals, and a second transistor having a control terminal and first and second controlled terminals, where
the first controlled terminal of the first transistor and the first controlled terminal of the second transistor are connected to one another and to a first reference potential, and
the second controlled terminal of the first transistor and the second controlled terminal of the second transistor are connected to a second reference potential,
wherein the first transistor and the second transistor are of a first conductivity type;
a first circuit having an input side connected to the second controlled terminal of the first transistor, the first circuit controlled by a first voltage which depends on a first input voltage which is applied to the control terminal of the first transistor, the first circuit having an output side configured to provide a first output current; and
a second circuit having an input side connected to the second controlled terminal of the second transistor, the second circuit controlled by a second voltage which depends on a second input voltage which is applied to a control terminal of the second transistor, the second circuit having an output side configured to provide a second output current;
wherein the first circuit and/or the second circuit has a transistor having a control terminal to which the first voltage or the second voltage is applied, wherein the transistor of the first circuit and/or the second circuit has a second conductivity type that is different from the first conductivity type.

2. The amplifier circuit as claimed in claim 1, further comprising:
a first current source configured to provide current to the first controlled terminal of the first transistor and/or the first controlled terminal of the second transistor.

3. The amplifier circuit as claimed in claim 2,
wherein the first current source has a first current source transistor which is connected between the first controlled terminal of the first transistor and the first reference potential, and a control input of the current source transistor is set up to receive a first bias voltage.

4. The amplifier circuit as claimed in claim 3, further comprising:
a first protective circuit connected in series with the first current source, between the first controlled terminal of the first transistor and the first current source,
wherein the first protective circuit is set up such that a voltage difference between the control terminal of the first current source transistor and the second controlled terminal of the first transistor is smaller than a predetermined maximum voltage.

5. The amplifier circuit as claimed in claim 1, further comprising:
a first bypass path connected in parallel with the first transistor and including a first bypass transistor, wherein a control input of the first bypass transistor is set up to receive a second bias voltage.

6. The amplifier circuit as claimed in claim 1, further comprising:
a second bypass path connected in parallel with the second transistor and having a third bypass transistor, wherein a control input of the third bypass transistor is set up to receive a third bias voltage.

7. The amplifier circuit as claimed in claim 4,
wherein the predetermined maximum voltage is equal to or less than an applicable operating voltage of the first transistor.

8. The amplifier circuit as claimed in claim 7,
wherein the predetermined maximum voltage is in a range of from 1.5 V to 4 V.

9. The amplifier circuit as claimed in claim 1,
wherein the first transistor and/or the second transistor are/is set up as a laterally-diffused metal-oxide semiconductor transistor.

10. The amplifier circuit as claimed in claim 1,
wherein a voltage difference between the first input voltage and the first reference potential is greater than an applicable operating voltage of the first transistor; and/or
wherein a voltage difference between the second input voltage and the first reference potential is greater than an applicable operating voltage of the second transistor.

11. The amplifier circuit as claimed in claim 1, further comprising
a circuit which provides a total output current which is dependent on the first output current and the second output current.

12. An amplifier circuit, comprising:
a first transistor having a control terminal and first and second controlled terminals, and a second transistor having a control terminal and first and second controlled terminals, where
the first controlled terminal of the first transistor and the first controlled terminal of the second transistor are connected to one another and to a first reference potential, and
the second controlled terminal of the first transistor and the second controlled terminal of the second transistor are connected to a second reference potential,
wherein the first transistor and the second transistor are of a first conductivity type;
a third transistor having a control terminal and first and second controlled terminals,
the first controlled terminal of the third transistor is connected to the second controlled terminal of the first transistor;
the control terminal of the third transistor is set up to receive a voltage which depends on a first input voltage which is applied to the control terminal of the first transistor;
the second controlled terminal of the third transistor is configured to provide a first output current; and
a fourth transistor having a control terminal and first and second controlled terminals,
the first controlled terminal of the fourth transistor is connected to the second controlled terminal of the second transistor;
the control terminal of the fourth transistor is set up to receive a voltage which depends on a second input voltage which is applied to the control terminal of the second transistor; and
the second controlled terminal of the fourth transistor is configured to provide a second output current; and
wherein the third transistor and the fourth transistor are of a second conductivity type which is different from the first conductivity type.

13. The amplifier circuit as claimed in claim 12, further comprising:
a first voltage source connected to the control terminal of the third transistor and set up to provide the voltage to the control terminal of the third transistor, the voltage depending on the first input voltage applied to the control terminal of the first transistor.

14. The amplifier circuit as claimed in claim 13, further comprising:
a second voltage source connected to the control terminal of the fourth transistor and set up to provide the voltage to the control terminal of the fourth transistor, the voltage depending on the second input voltage applied to the control terminal of the second transistor.

15. The amplifier circuit as claimed in claim 14,
wherein the first voltage source and the second voltage source form a joint voltage source which is set up to provide the same voltage to the control terminal of the third transistor and to the control terminal of the fourth transistor, wherein the voltage depends on the first input voltage which is applied to the control terminal of the first transistor and on the second input voltage which is applied to the control terminal of the second transistor.

16. The amplifier circuit as claimed in claim 12, further comprising:
a second current source which is connected between the second controlled terminal of the first transistor and the second reference potential.

17. An amplifier circuit, comprising:
a pair of input differential transistors; and
at least one pair of folded-cascode transistors having a conductivity type that differs from a conductivity type of the input differential transistors;
wherein each controlled terminal of a transistor of the pair of input differential transistors is connected to a controlled terminal of an associated transistor of the pair of folded-cascode transistors; and
wherein each control terminal of a transistor of the pair of folded-cascode transistors is set up to receive a voltage which depends on a respective input voltage which is applied to a control terminal of an associated transistor of the pair of input differential transistors.

18. The amplifier circuit as claimed in claim 17, further comprising:
a first current source configured to provide current to a first controlled terminal of each transistor in the pair of input differential transistors.

19. The amplifier circuit as claimed in claim 18, further comprising:
a first protective circuit connected in series with the first current source, between the first controlled terminal of each transistor of the pair of input differential transistors and the first current source,
wherein the first protective circuit is set up such that a voltage difference between a control terminal of the first current source and the respective second controlled terminal of the transistors of the pair of input differential transistors is smaller than a predetermined maximum voltage.

20. An amplifier circuit, comprising:
a first transistor having a control terminal and first and second controlled terminals, and a second transistor having a control terminal and first and second controlled terminals, where
the first controlled terminal of the first transistor and the first controlled terminal of the second transistor are connected to one another and to a first reference potential,
a first circuit having an input side connected to the second controlled terminal of the first transistor, the first circuit controlled by a first voltage which depends on a first input voltage which is applied to the control terminal of the first transistor, the first circuit having an output side configured to provide a first output current; and
a second circuit having an input side connected to the second controlled terminal of the second transistor, the second circuit controlled by a second voltage which depends on a second input voltage which is applied to a control terminal of the second transistor, the second circuit having an output side configured to provide a second output current;
wherein the first voltage is independent of the second voltage.
